(19) United States
(12) Patent Application Publication
(10) Pub. No.: US 2007/0228389 A1
(43) Pub. Date: Oct. 4, 2007

(54) Thin film transistor array substrate and electronic ink display device

(75) Inventors: Yu-Chen Hsu, Hsinchu (TW); Chi-Ming Wu, Hsinchu (TW)

Correspondence Address: SHEEHAN PHINNEY BASS & GREEN, PA;c/o PETER NIEVES, 1000 ELM STREET, MANCHESTER, NH, 03105-3701, US

(73) Assignee: PRIME VIEW INTERNATIONAL CO., LTD., HSINCHU (TW)

(21) Appl. No.: 11/651,645

(22) Filed: Jan. 10, 2007

(30) Foreign Application Priority Data
Mar. 31, 2006 (TW) 95111650

(51) Int. Cl. H01L 33/00; H01L 31/12

(52) U.S. Cl. 257/79

(57) ABSTRACT

A thin film transistor (TFT) array substrate including a substrate, multiple scan lines, multiple data lines and multiple pixel units is provided. Each pixel unit includes a TFT and a pixel electrode. The pixel electrode is disposed above the TFT and electrically connected thereto. The TFT includes a first gate electrode, a first insulating layer, a semiconductor layer, a source electrode, a drain electrode, a second insulating layer and at least one second gate electrode. The second gate electrode is disposed on the second insulating layer positioned above the semiconductor layer and is electrically connected to the first gate electrode. The second gate electrode can be used to reduce the current leakage through the TFT. Moreover, an electronic ink display device comprising the above TFT array substrate is provided.

### RELATED APPLICATIONS

The present application is based on, and claims priority from, Taiwan Application Serial Number 95111650, filed Mar. 31, 2006, the disclosure of which is hereby incorporated by reference herein in its entirety.

### BACKGROUND

1. Field of Invention

The present invention relates to an array substrate and display device. More particularly, the present invention relates to a thin film transistor array is substrate and electronic ink display device.

2. Description of Related Art

Regarding the developing of display technology, there are many novel display devices exploited by inventors. Novel display devices include the electronic ink display. The electronic ink display has many advantages such as low power consumption, long user life, flexible and so on.

The development of electronic ink displays began in the 1970s. The electronic ink display comprises many charged balls. One side of each ball is white and the other side is black. When the electric field in the electronic ink display is altered, the balls rotate and display different colors. The second generation of electronic ink displays started in the 1990s. In this generation, microcapsules replace the traditional balls. The microcapsules are filled with colorful oil and a plurality of white charged particles. Through the external electric field altering, the particles will start moving. When the particles move upward, it displays white color. When the particles move downward, it displays colored oil.

Referring to FIG. 1A, a cross-sectional diagram shows an ordinary electronic ink display device structure. FIG. 1B shows a vertical view of a thin film transistor (TFT) array substrate of the electronic ink display device in FIG. 1A. FIG. 1A is a cross-sectional view of the A-A′ line in FIG. 1B. Referring to FIG. 1A and FIG. 1B, the electronic ink display device 10 comprises a TFT array substrate 20 and a front panel 30, wherein the front panel 30 is disposed on one side of the TFT array substrate 20.

The front panel 30 includes a cover 32, a transparent electrode 34 and an electronic ink layer 36. The electronic ink layer 36 comprises a plurality of electronic ink particle 36a. The electronic ink layer 36 is sandwiched in between the transparent electrode 34 and the TFT array substrate 20.

The TFT array substrate 20 includes a substrate 21, a plurality of scan lines 22 and data lines 23, a plurality of TFTs 24, a dielectric layer 25 and a plurality of pixel electrodes 26. The scan lines 22 and the data lines 23 define the substrate 21 into a plurality of pixel regions 21a. Each of the TFT 24 is placed in respective pixel region 21a and electrically connected to the respective scan line 22 and the respective data line 23. Referring to FIG. 1A, the TFT 24 includes a gate electrode 24a, a gate dielectric 24b, a semiconductor layer 24c, a source electrode 24d and a drain electrode 24e. The TFT 24 has only one gate electrode 24a and the gate electrode 24a is placed below the semiconductor 24c, therefore, the TFT 24 is called bottom gate TFT. Referring to FIG. 1A and FIG. 1B, dielectric layer 25 covers the scan lines 22, the data lines 23 and the TFTs 24. The dielectric layer 25 has at least one opening H to expose partial drain electrode 24e located in the TFT 24. The pixel electrode 26 is disposed on the dielectric layer 25 and it is electrically connected to the TFT 24 through the opening H. By the operation of the scan line 22, the data line 23 and the TFT 24, the pixel electrode 26 will receive a data voltage. Particularly, to get a better aperture ratio, pixel electrode 26 is placed above the TFT 24.

As the above mentioned, when the pixel electrode 26 receives a data voltage, an electric field is formed in between the pixel electrode 26 and the transparent electrode 34. The electric field will start driving the ink particles 36a. Besides, in the process refreshing the image, the gate electrode 24a and the respective scan line 22 in the inactive pixels will receive a low gate voltage to make the TFT 24 in the closure status.

As mentioned above, the pixel electrode 26 is placed above the TFT 24. Therefore, when the pixel electrode 26 receives a data voltage, it will become as another gate electrode of TFT 24. Therefore, the electric field contributed by the pixel electrode 26 rearranges the electric charges of the semiconductor layer 24c and produce a channel in the semiconductor layer 24c. The electric charges of the pixel electrode 26 leaks through the semiconductor layer 24c. It forms a current leakage problem. Therefore, the data voltage on the pixel electrode 26 is not stable. It deteriorates the display quality of the electronic ink display device.

### SUMMARY

A thin film transistor (TFT) array substrate is provided. The thin film transistor array substrate includes a substrate, multiple scan lines, multiple data lines and multiple pixel units. The scan lines and the data lines are disposed on the substrate. Each pixel unit is electrically connected to at least one scan line and at least one data line. Each pixel unit includes a TFT and a pixel electrode electrically connected to TFT. The pixel electrode is disposed above the TFT. The TFT includes a first gate electrode, a first insulating layer, a semiconductor layer, a source electrode, a drain electrode, a second insulating layer and at least one second gate electrode. The first gate electrode is electrically connected to the respective scan lines. The first insulating layer is overlaid on the first gate electrode. The semiconductor layer is placed on the first insulating layer positioned above the first gate electrode. The source electrode and drain electrode are on the semiconductor layer and partially overlaid on it. The source electrode is electrically connected to the respective data line. The second insulating layer covers the source electrode, the drain electrode and the semiconductor layer. The second gate electrode is disposed on the second insulating layer positioned above the semiconductor layer. The second gate electrode is electrically connected to the first gate electrode.

An electronic ink display device containing the above TFT array substrate is provided. The electronic ink display device comprises a TFT array substrate given above and a front panel placed on one side of the TFT array substrate. The front panel comprises a cover, a transparent electrode layer and an electronic ink layer. The transparent electrode layer is placed below the cover. The electronic ink layer is placed in between the transparent electrode layer and the TFT array substrate.

### BRIEF DESCRIPTION OF THE DRAWINGS

These and other features, aspects, and advantages of the present invention will become better understood with regard to the following description, appended claims, and accompanying drawings where:

FIG. 1A shows a cross-sectional structure of an ordinary electronic ink display device.

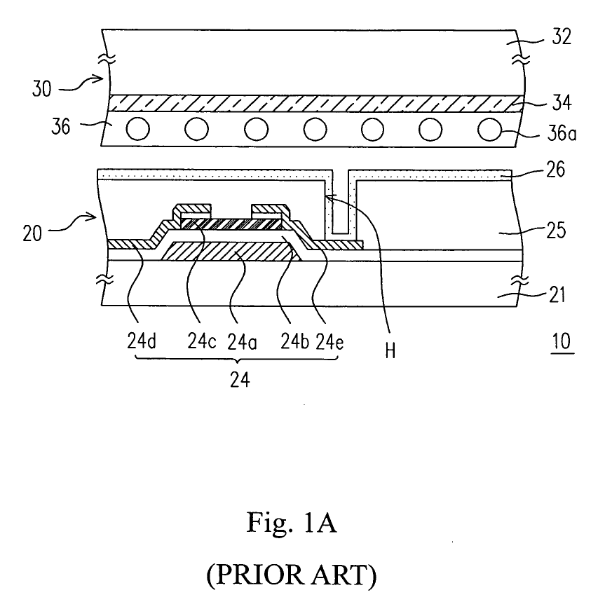

FIG. 1B shows a vertical view of the ordinary electronic ink display device in FIG. 1A

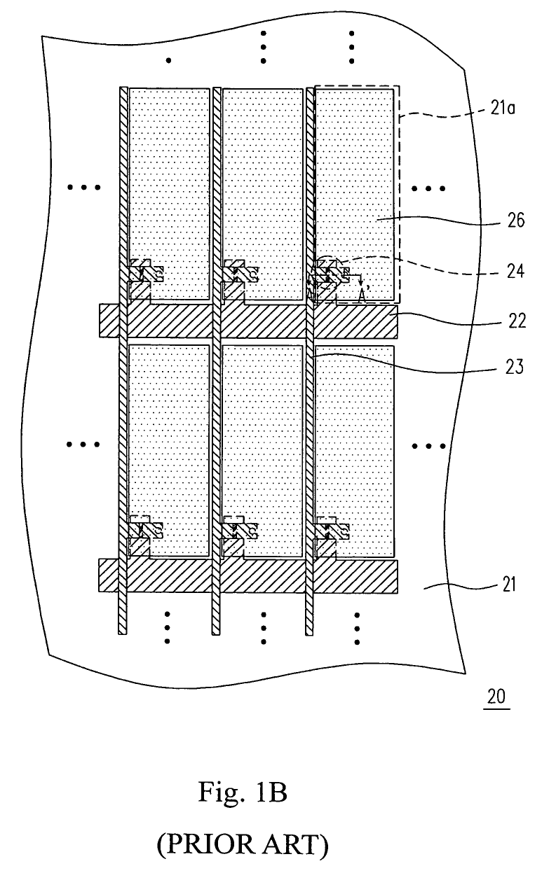

FIG. 2A shows a vertical view of a TFT array substrate according to the embodiment of this invention

FIG. 2B shows a cross-sectional view of B-B′ line in FIG. 2A

FIG. 2C shows a cross-sectional view of C-C′ line in FIG. 2A

FIG. 3A shows an electronic ink display device according to the embodiment of this invention

FIG. 3B shows an electronic ink display device according to another embodiment of this invention.

### DETAILED DESCRIPTION

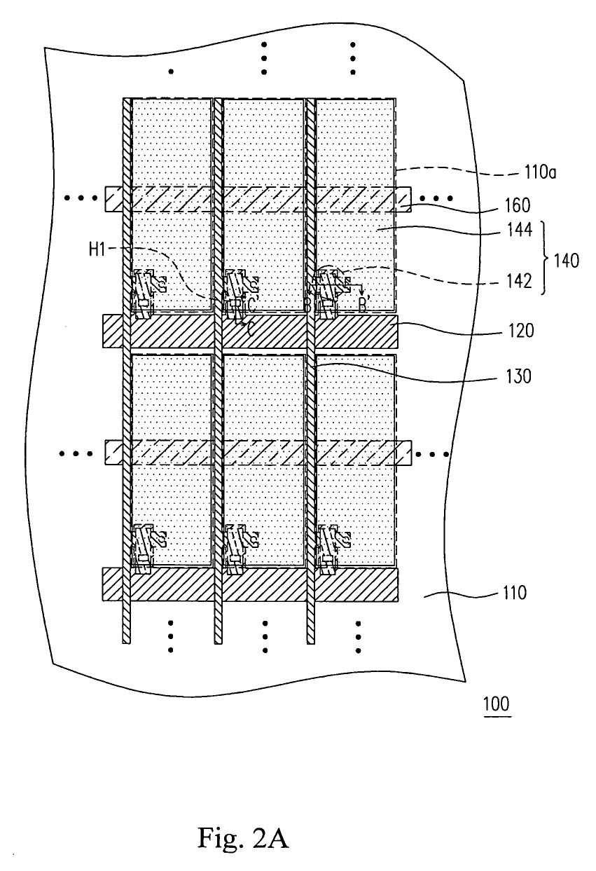

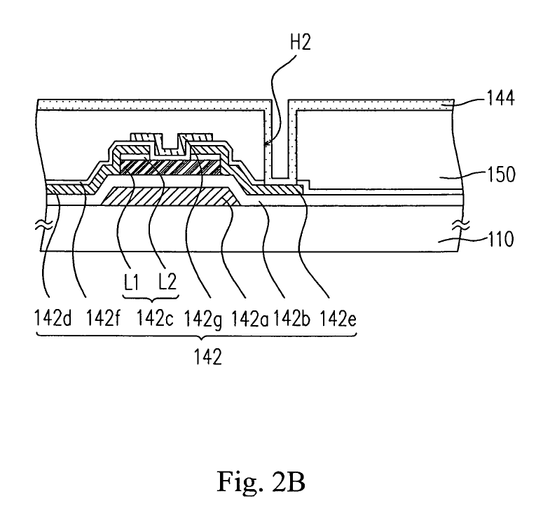

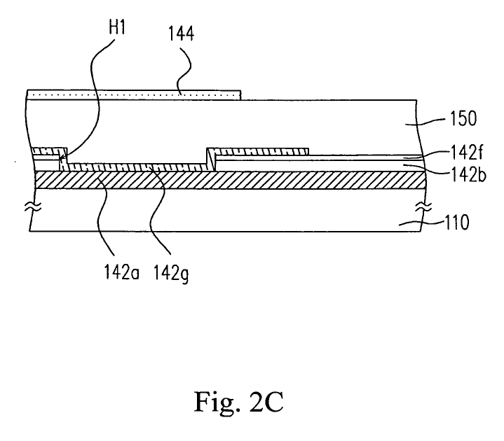

In an exemplary embodiment of the present invention, FIG. 2A is a vertical view of a TFT array substrate. FIG. 2B is a cross-sectional view of the B-B′ line in FIG. 2A. and FIG. 2C is a cross-sectional view of the C-C′ line in FIG. 2A.

Referring to the FIG. 2A and FIG. 2B, TFT array substrate 100 includes a substrate 110, a plurality of scan lines 120, a plurality of data lines 130 and a plurality of pixel units 140. The scan lines 120 and data lines 130 are placed on the substrate 110. Each of the pixel units 140 is electrically connected to the respective scan line 120 and data line 130. Each of the pixel units 140 comprises a TFT 142 and a pixel electrode 144 electrically connected to the TFT 142. The pixel electrode 144 is placed above the TFT. The TFT 142 comprises a first gate electrode 142a, a first insulating layer 142b, a semiconductor layer 142c, a source electrode 142d, a drain electrode 142e, a second insulating layer 142f and at least one second gate electrode 142g. The first gate electrode 142a is electrically connected to the respective scan line 120. The first insulating layer 142b is overlaid on the first gate electrode 142a. The semiconductor layer 142c is placed on the first insulating layer 142b positioned above the first gate electrode 142a. The source electrode 142d and the drain electrode 142e are disposed on the semiconductor layer 142c and partially overlaid on the semiconductor layer 142c. The source electrode 142d is electrically connected to the respective data line 130. The second insulating layer 142f covers the source electrode 142d, drain electrode 142e and the semiconductor layer 142c. The second gate electrode 142g is disposed on the second insulating layer 142f positioned above the semiconductor layer 142c. The second gate electrode 142g is electrically connected to the first gate electrode 142a.

Accordingly, the TFT 142 has a first gate electrode 142a and a second gate electrode 142g. The second gate electrode 142g is placed in between the semiconductor layer 142c and the pixel electrode 144. The second gate electrode 142g is electrically connected to the first gate electrode 142a.

Referring to FIG. 2A and FIG. 2C, in an exemplary embodiment of the present invention, the part between the first insulating layer 142b and the second insulating layer 142f has a first opening H1. The first opening H1 exposes a partial part of the first gate electrode 142a. The second gate electrode 142g is electrically connected to the first gate electrode 142a through the first opening H1. The electrically connecting style of the first gate electrode 142a and the second gate electrode 142g is not limited to the embodiment given above. There are other suitable electrically connecting methods for the first gate electrode 142a and the second gate electrode 142g.

Referring to the FIG. 2B, when the first gate electrode 142a receives a voltage and following switch on the TFT 142, the second gate electrode 142g receives the same voltage. As the above mentioned, when the TFT 142 is switched on, the pixel electrode 144 receives a positive data voltage. Due to the location of second gate electrode 142g is between of the semiconductor layer 142c and the pixel electrode 144, the electric field provided by the electric charges of the pixel electrode 144 is shielded. Therefore, it does not produce a channel in the semiconductor layer 142c and will successfully avoid the problem of current leakage. In another aspect, the TFT on/off switch 142 is not affected by the pixel electrode 144, it is only affected by the voltage signal of the first gate electrode 142a.

The semiconductor layer 142c in the present invention is not affected by the pixel electrode 144 to produce a channel in the semiconductor layer 142c. The electric charges of the pixel electrode 144 will not leak through the semiconductor layer 142c. Consequently, the TFT array substrate 100 current leakage problem can be reduced, thereby the data voltage on the pixel electrode 144 can be retained for a longer time. Besides, due to the double-gate electrode of TFT 142 in the invention, the pixel electrode 144 can be designed to cover the whole pixel region 110a. Even though the pixel electrode 144 is in the above design condition, the TFT on/off switch is not affected by the pixel electrode 144. Therefore, the aperture ratio of the pixel electrode 144 and display area can be increased.

Still referring to FIG. 2A, in one embodiment, the material of the substrate 110 may be glass, quartz and other suitable material. The material of the scan lines 120 and data lines 130 includes metal, alloy and other suitable conductive material.

In one embodiment, the first gate electrode 142a and the scan lines 120 are on the same layer. The material of the first insulating layer 142b and the second insulating layer 142f comprises silicon oxide, silicon nitride, silicon oxynitride and other suitable dielectric materials. The material of the semiconductor layer 142c comprises amorphous silicon, polysilicon and other suitable semiconductor layer material. In one embodiment, semiconductor layer 142c comprises a channel layer L1 and an ohmic contact layer L2. The ohmic contact layer L2 is disposed among the channel layer L1, the source electrode 142d and the drain electrode 142e. The material of the ohmic contact layer L2 may be doped amorphous silicon. The material of the source electrode 142d and the drain electrode 142e comprises chromium, aluminum alloy and other suitable conductive material. The source electrode 142d, the drain electrode 142e and the data lines 130 are on the same layer. The second gate electrode 142g may be metal, alloy or other suitable conductive material. The material of pixel electrode 144 includes indium tin oxide, indium zinc oxide, metal and the combination thereof.

In one embodiment, further comprising a plurality of common wires 160 placed on the substrate 110 to improve the efficiency of data voltage retention. Each of the common wires 160 is parallel to the scan line 120 and is located between the two adjacent scan lines 120. Particularly, each pixel electrode 144 and each common wire 160 located below the pixel electrode 144 forms a storage capacitor. The storage capacitor stabilizes the data voltage on the pixel electrode 144 and further improves the display performance of each pixel unit 140. In the other embodiment, the common wires 160 are not necessarily required on the TFT array substrates. The requirement of the common wires 160 is upon on the product design.

Accordingly, the TFT array substrate 100 has a double-gate electrode structure. The second gate electrode 142g is located between the semiconductor layer 142c and the pixel electrode 144. The second gate electrode 142g can be used to shield the electric field produced by the electric charges of the pixel electrode 144. Therefore, the semiconductor layer 142c is not affected by pixel electrode 144 electric charges to produce a channel in the semiconductor layer 142c. In another aspect, the electric charges of the pixel electrode 144 will not leak through the semiconductor layer 142c when the TFT 142 switches off. Therefore, the TFT array substrate 100 of the present invention comprises the advantages described below, such as low current leakage, more stable data voltage on the pixel electrode 144, better aperture ratio and larger display area for each pixel unit 140.

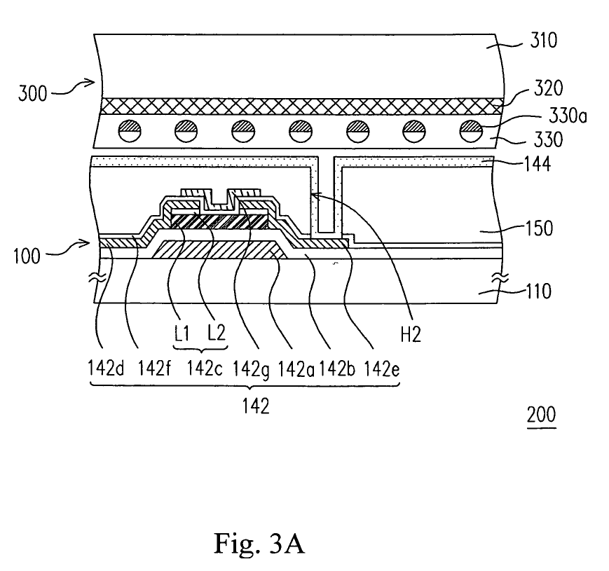

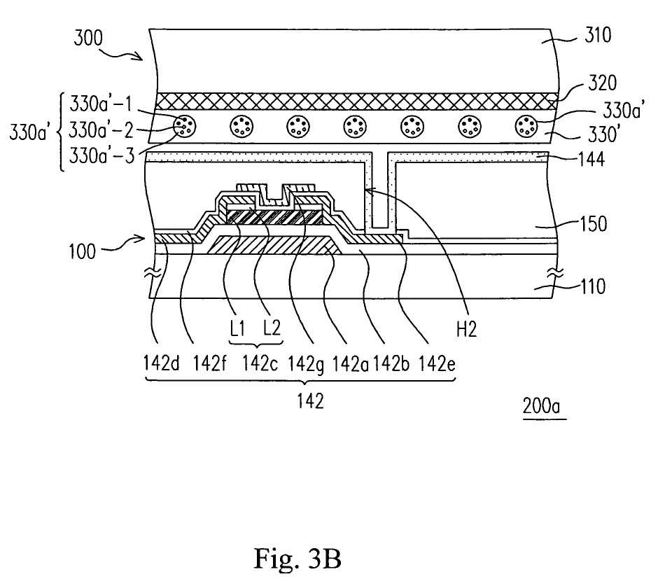

The above-mentioned TFT array substrate of the embodiment of present invention can be used to fabricate an electronic ink display device. FIG. 3A is a cross-sectional view of an electronic ink display device according to one embodiment of the present invention. Referring to the FIG. 3A, the electronic ink display device 200 comprises the above-mentioned TFT array substrate 100 and a front panel 300. The front panel 300 is placed on one side of the TFT array substrate 100. The front panel 300 comprises a cover 310, a transparent electrode 320 and an electronic ink layer 330. The transparent electrode is placed below the cover 310. The electronic ink layer 330 is sandwiched between the transparent electrode 320 and the TFT array substrate 100.

The detailed structure of the TFT array substrate 100 is discussed in the above. Significantly, the electronic ink display device 200 in the FIG. 3A comprises the TFT array substrate 100 comprising of the double-gate electrode structure given above. The second gate electrode 142g is located between the semiconductor layer 142c and the pixel electrode 144. The second gate electrode 142g can be used to shield the electric field produced by the electric charges of the pixel electrode 144. Therefore, the semiconductor layer 142c is not affected by the pixel electrode 144 to produce a channel in the semiconductor layer 142c. In another aspect, the electric charges of the pixel electrode 144 do not leak through the semiconductor layer 142c when the TFT 142 switches off. The problem of current leakage can be substantially reduced.

Due to the reduced current leakage, the data voltage of the pixel electrode 144 can be retained for a longer time. Therefore, the display of each pixel is more stable. In the structure given above, even though the pixel electrode 144 is designed to cover the whole pixel region 110a, the on/off switch of the TFT 142 is not affected by the pixel electrode 144. Therefore, the aperture ratio of the pixel electrode 144 and the display area can be increased.

Referring to the FIG. 3A, in one embodiment of the present invention, the material of the cover 310 comprises glass, quartz, acrylic and other suitable material. The material of transparent electrode 320 comprises Indium Tin Oxide, Indium Zinc Oxide and other conducting material.

In one embodiment, the electronic ink layer 330 comprises a plurality of electronic ink particles 330a. Each of the electronic ink particles 330a have bright colors one side and dark colors on the other side. Moreover, the two sides of the electronic ink particles 330a have opposite polarity. When the electric field between the pixel electrode 144 and the transparent electrode 320 is altered, the electronic ink particles 330a in the electronic ink layer 330 is driven, the electronic ink display device 200 displays an image.

The electronic ink layer 330 is not limited to the type given above. FIG. 3B provides a cross-sectional view of the electronic ink display device according to the other embodiment of the present invention. In the electronic ink display device 200a, the electronic ink layer 330′ comprises a plurality of dark particles 330a′-1, a plurality of bright particles 330a′-2 and a transparent fluid 330a′-3. The dark particles 330a′-1 and the bright particles 330a′-2 are distributed over the transparent fluid 330a′-3. The dark particles 330a′-1 and the bright particles 330a′-2 have opposite polarity. When the electric field between the pixel electrode 144 and the transparent electrode 320 is altered, the dark particles 330a′-1 and the bright particles 330a′-2 start moving upward or downward according to the direction of the electric field. The movement described above provides the display for each pixel unit. In the other embodiment of the present invention, the dark particles 330a′-1, the bright particles 330a′-2 and the transparent fluid are packaged in a plurality of microcapsules 330a′.

In the other embodiment of the present invention, the dark particles 330a′-1, the bright particles 330a′-2 and the transparent fluid 330a′-3 are placed in a plurality of microcups. In the other embodiment of the present invention, dark particles 330a′-1, bright particles 330a′-2 and the transparent fluid 330a′-3 can be moving in the active region without being limited to the lateral structure. In the other embodiment of the present invention, dark particles 330a′-1, bright particles 330a′-2 and the transparent fluid 330a′-3 can be placed in the different structure. Accordingly, due to the use of the TFT array substrate 100 given above in the electronic ink display device 200, the electronic ink display device 200 has a better display quality.

Applying the TFT array substrate and the electronic ink display device described above at least comprises the advantages below:

(1) Due to the double-gate electrode structure in the TFT array substrate, the current leakage problem can be reduced.

(2) Due to the reduction of current leakage, the data voltage on the pixel electrode is more stable.

(3) Even though the pixel electrode wholly covers the TFT, the operation of TFT is not affected. Therefore, the aperture ratio of each pixel and display area can be increased.

(4) Due to the decreased current leakage in the TFT array substrate of the present invention, the display apparatus includes the TFT array substrate given above has a better display quality.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A thin film transistor array substrate, comprising:
a substrate;
a plurality of scan lines and a plurality of data lines disposed on the substrate;
a plurality of pixels, each of the pixels being electrically connected to one of the scan lines and one of the data lines, each of the pixels comprising a thin film transistor and a pixel electrode electrically connected to the thin film transistor, the pixel electrode being positioned above the thin film transistor, wherein the thin film transistor comprises:
a first gate electrode electrically connected to its respective scan line;
a first insulating layer overlaid on the first gate electrode;
a semiconductor layer disposed on the first insulating layer positioned above the first gate electrode;
a source electrode and a drain electrode disposed on the semiconductor layer and partially overlaid on the semiconductor layer, the source electrode being electrically connected to the respective data line, the drain electrode being electrically connected to the respective pixel electrode;
a second insulating layer overlaid on the source electrode, the drain electrode and the semiconductor layer; and
at least one second gate electrode disposed on the second insulating layer positioned above the semiconductor layer and electrically connected to the first gate electrode.

2. The thin film transistor array substrate of claim 1, wherein the first insulating layer and the second insulating layer have an opening to expose part of the first gate electrode, thereby, the second gate electrode and the first gate electrode are electrically connected through the opening.

3. The thin film transistor array substrate of claim 1, further comprising a plurality of common wires disposed on the substrate, the common wires being parallel to the scan lines and placed between the adjacent scan lines.

4. The thin film transistor array substrate of claim 1, wherein the pixel electrode comprises a material selected from a group consisting of indium tin oxide, indium zinc oxide, metal and a combination thereof.

5. An electronic ink display device, comprising:
a thin film transistor array substrate of claim 1; and
a front panel, disposed on one side of the thin film transistor array substrate, the front panel comprising:
a cover;
a transparent electrode layer disposed under the cover; and
an electronic ink layer, sandwiched in between the transparent electrode layer and the thin film transistor array substrate.

6. The electronic ink display device of claim 5, wherein the first insulating layer and the second insulating layer have an opening to expose part of the first gate electrode, thereby, the second gate electrode and the first gate electrode are electrically connected through the opening.

7. The electronic ink display device of claim 5, further comprising a plurality of common wires disposed on the substrate, the common wires being parallel to the scan line and placed between the adjacent scan lines.

8. The electronic ink display device of claim 5, wherein the pixel electrode comprises a material selected from a group consisting of indium tin oxide, indium zinc oxide, metal and a combination thereof.

9. The electronic ink display device of claim 5, wherein the electronic ink layer comprises a plurality of electronic ink particles and a transparent fluid.

10. The electronic ink display device of claim 9, wherein the electronic ink particles comprises a plurality of dark particles and a plurality of bright particles, the dark particles and the bright particles are distributed over the transparent fluid, the dark particles and the bright particles have opposite polarity.

11. The electronic ink display device of claim 10, further comprising a plurality of microcapsules, the dark particles, the bright particles and the transparent fluid being packaged in the microcapsules.

12. The electronic ink display device of claim 10, further comprising a plurality of microcups, the dark particles, the bright particles and the transparent fluid being placed in the microcups.

13. The electronic ink display device of claim 5, wherein the electronic ink layer comprises a plurality of electronic ink particles, each of the electronic ink particles has a bright color on one half of the electronic ink particles and a dark color on the other half of the electronic ink particles, each side of the electronic ink particles has opposite polarity.
